(19) United States
(12) Patent Application Publication
(10) Pub. No.: US 2026/0018367 A1
(43) Pub. Date: Jan. 15, 2026

(54) THERMALLY OPTIMIZED EXTRACTION PLATE FOR ION IMPLANTER

(71) Applicant: Applied Materials, Inc., Santa Clara, CA (US)

(72) Inventors: Adam M. McLaughlin, Merrimac, MA (US); Craig R. Chaney, Gloucester, MA (US)

(21) Appl. No.: 18/769,008

(22) Filed: Jul. 10, 2024

(51) Int. Cl. H01J 37/08; H01J 37/147; H01J 37/317

(52) U.S. Cl. CPC H01J 37/08; H01J 37/1471; H01J 37/3171; H01J 2237/0451

(57) ABSTRACT

An ion source and ion implantation system are disclosed that utilize an extraction plate that controls the flow of heat to create a region around the extraction aperture that has an elevated temperature. The extraction plate has thicker portions that correspond to the hottest components in the ion source. These thicker portions extend toward the extraction aperture to bring the heat toward the extraction aperture. The thicker portions may be located directly above the plasma generator, which may be an indirectly heated cathode. Further, the thicker portions may also be located directly above the repeller and/or side electrodes.

### FIELD

Embodiments of the present disclosure relate to systems wherein the thickness of the extraction plate is varied for purposes of creating preferred thermally conductive paths.

### BACKGROUND

The fabrication of a semiconductor device involves a plurality of discrete and complex processes. These processes may be performed using a workpiece processing system. This workpiece processing system may be a beam-line ion implantation system or a plasma processing chamber, for example. In certain embodiments, the temperatures of the components in the workpiece processing system are highly relevant to the process being performed.

For example, a feed gas may be ionized in an ion source and extracted through an extraction aperture disposed on an extraction plate. This extraction plate may be made of metal. If the temperature of the extraction plate in the vicinity of the extraction aperture is sufficiently low, feed gas may condense on the extraction plate proximate the extraction aperture. This condensed feed gas becomes a deposition on the extraction plate. If the deposition occurs along the walls forming the extraction aperture, the extracted ion beam may become partially blocked, resulting in a nonuniform process.

Thus, in certain embodiments, it may be beneficial to maintain the region around the extraction aperture at as high a temperature as possible. Further, it would be advantageous if the design of the extraction plate took advantage of known hot regions within the ion source to achieve this elevated temperature.

### SUMMARY

An ion source and ion implantation system are disclosed that utilize an extraction plate that controls the flow of heat to create a region around the extraction aperture that has an elevated temperature. The extraction plate has thicker portions s that correspond to the hottest components in the ion source. These thicker portions extend toward the extraction aperture to bring the heat toward the extraction aperture. The thicker portions may be located directly above the plasma generator, which may be an indirectly heated cathode. Further, the thicker portions may also be located directly above the repeller and/or side electrodes.

According to one embodiment, an ion source is disclosed. The ion source comprises an arc chamber having a first end, a second end and side walls connecting the first end and the second end, wherein a direction from the first end to the second end is defined as a width direction and a direction from a first sidewall to an opposite sidewall is defined as a height direction; a cathode disposed within the arc chamber at the first end; and an extraction plate disposed on the arc chamber, the extraction plate comprising: an extraction aperture; a first thicker portion disposed above the cathode, referred to as a cathode heat capture region; and a second thicker portion, referred to as a cathode heat conduction region, disposed in the width direction between the cathode heat capture region and the extraction aperture, wherein heat from the cathode travels through the cathode heat capture region and the cathode heat conduction region to an area around the extraction aperture to increase a temperature of the area. In some embodiments, the arc chamber comprises a repeller disposed at the second end; and the extraction plate comprises: a third thicker portion disposed above the repeller, referred to as a repeller heat capture region; and a fourth thicker portion, referred to as a repeller heat conduction region, disposed in the width direction between the repeller heat capture region and the extraction aperture, wherein heat from the repeller travels through the repeller heat capture region and the repeller heat conduction region to the area around the extraction aperture to increase the temperature of the area. In certain embodiments, the cathode heat capture region and the repeller heat capture region are a same shape and size, and the cathode heat conduction region and the repeller heat conduction region are a same shape and size. In some embodiments, the cathode heat conduction region is narrower in the height direction than the cathode heat capture region. In some embodiments, the cathode heat capture region comprises a rectangular prism. In some embodiments, the cathode heat capture region has a thickness that corresponds to a shape of the cathode. In some embodiments, the cathode heat conduction region comprises a rectangular prism having a height less than a height of the cathode heat capture region. In some embodiments, the cathode heat conduction region comprises a curved shape having a distal end in contact with the cathode heat capture region and a proximal end near the extraction aperture, smaller in a height direction than the distal end. In some embodiments, the cathode heat conduction region comprises a linearly sloped shape having a distal end in contact with the cathode heat capture region and a proximal end near the extraction aperture, smaller in a height direction than the distal end. In some embodiments, the cathode heat capture region and the cathode heat conduction region comprise a plurality of cathode conduction fingers that merge at or before the extraction aperture. In some embodiments, the cathode heat capture region does not contact the first end or the side walls. In some embodiments, the arc chamber comprises a side electrode disposed at one of the side walls; and the extraction plate comprises: a third thicker portion disposed above the side electrode, referred to as an electrode heat capture region; and a fourth thicker portion, referred to as an electrode heat conduction region, disposed in the height direction between the electrode heat capture region and the extraction aperture, wherein heat from the side electrode travels through the electrode heat capture region and the electrode heat conduction region to the area around the extraction aperture to increase the temperature of the area.

According to another embodiment, an ion implantation system is disclosed. The ion implantation system comprises any of the ion sources described above to generate an ion beam; a workpiece holder to hold a workpiece; and one or more beamline components disposed between the ion source and the workpiece holder to guide the ion beam toward the workpiece.

According to another embodiment, an extraction plate for use with an indirectly heated cathode ion source and adapted to be disposed on an arc chamber containing a cathode at a first end and a repeller at a second end is disclosed. The extraction plate comprises an extraction aperture; a first thicker portion disposed above the cathode, referred to as a cathode heat capture region; a second thicker portion, referred to as a cathode heat conduction region, disposed in a width direction between the cathode heat capture region and the extraction aperture, wherein heat from the cathode travels through the cathode heat capture region and the cathode heat conduction region to an area around the extraction aperture to increase a temperature of the area; a third thicker portion disposed above the repeller, referred to as a repeller heat capture region; and a fourth thicker portion, referred to as a repeller heat conduction region, disposed in the width direction between the repeller heat capture region and the extraction aperture, wherein heat from the repeller travels through the repeller heat capture region and the repeller heat conduction region to the area around the extraction aperture to increase the temperature of the area. In some embodiments, the cathode heat capture region and the repeller heat capture region are a same shape and size, and the cathode heat conduction region and the repeller heat conduction region are a same shape and size. In some embodiments, the cathode heat capture region and the repeller heat capture region each comprises a rectangular prism. In some embodiments, the cathode heat capture region has a thickness that corresponds to a shape of the cathode and the repeller heat capture region has a thickness that corresponds to a shape of the repeller. In some embodiments, the cathode heat conduction region and the repeller heat conduction region are each larger than the extraction aperture in a height direction. In some embodiments, the cathode heat conduction region and the repeller heat conduction region each comprises a rectangular prism having a height less than a height of the cathode heat capture region and the repeller heat capture region, respectively. In some embodiments, the cathode heat conduction region and the repeller heat conduction region each comprises a curved shape or a linearly sloped shape having a distal end in contact with the cathode heat capture region and the repeller heat capture region, respectively and a proximal end near the extraction aperture, smaller in a height direction than the distal end.

### BRIEF DESCRIPTION OF THE FIGURES

For a better understanding of the present disclosure, reference is made to the accompanying drawings, which are incorporated herein by reference and in which:

FIG. 1 shows an indirectly heated cathode ion source according to one embodiment that may utilize the extraction plate described herein;

FIGS. 2A-2D show several embodiments of an extraction plate that may be used with the ion source of FIG. 1 that increases the temperature of the region surrounding the extraction aperture;

FIG. 3 shows another embodiment of an extraction plate that may be used with the ion source of FIG. 1 that increases the temperature of the region surrounding the extraction aperture;

FIG. 4 shows an indirectly heated cathode ion source according to another embodiment that may utilize the extraction plate described herein;

FIG. 5 shows one embodiment of an extraction plate that may be used with the ion source of FIG. 4 that increases the temperature of the region surrounding the extraction aperture; and

FIG. 6 shows an ion implantation system that utilizes any of the extraction plates described herein.

### DETAILED DESCRIPTION

As described above, varying the amount of material is one method of creating preferred thermally conductive paths in a component. Traditional subtractive processes may be used to remove material from certain regions to create thicker and thinner regions. Alternatively, additive manufacturing may be used to create the extraction plates described herein.

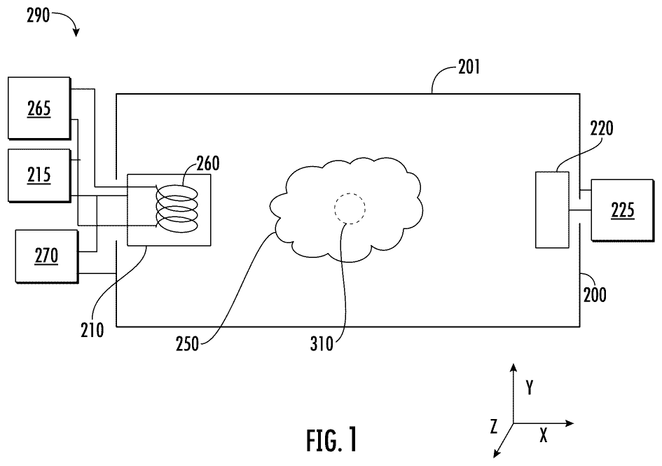

FIG. 1 shows a first embodiment of an ion source using an indirectly heated cathode that may utilize the disclosed extraction plate. FIG. 1 is a cross-sectional view of the ion source 290 that includes a repeller 220. The ion source 290 includes an arc chamber 200, comprising two opposite ends, and side walls 201 connecting to these ends. The arc chamber 200 also includes a bottom wall and an extraction plate. The walls of the arc chamber 200 may be constructed of an electrically conductive material, such as tungsten, and may be in electrical communication with one another. Note that the arc chamber 200 may be formed using two discrete ends, side walls 201 and a bottom wall. Alternatively, the arc chamber may be a unitary piece having the recited components. In some embodiments, the ion source 290 is an indirectly heated cathode (IHC) ion source. A cathode 210 is disposed in the arc chamber 200 at a first end of the arc chamber 200. A filament 260 is disposed behind the cathode 210. The cathode 210 may be a hollow cylinder with a closed end as the front surface. The side walls of the hollow cylinder serve to protect the filament 260. The filament 260 is in communication with a filament power supply 265. The filament power supply 265 is configured to pass a current through the filament 260, such that the filament 260 emits thermionic electrons. Cathode bias power supply 215 biases filament 260 negatively relative to the cathode 210, so these thermionic electrons are accelerated from the filament 260 toward the cathode 210 and heat the cathode 210 when they strike the back surface of cathode 210. The cathode bias power supply 215 may bias the filament 260 so that it has a voltage that is between, for example, 200V to 1500V more negative than the voltage of the cathode 210. The cathode 210 then emits thermionic electrons on its front surface into the arc chamber 200.

Thus, the filament power supply 265 supplies a current to the filament 260. The cathode bias power supply 215 biases the filament 260 so that it is more negative than the cathode 210, so that electrons are attracted toward the cathode 210 from the filament 260. Additionally, the cathode 210 is electrically biased relative to the arc chamber 200, using cathode power supply 270.

In this embodiment, a repeller 220 is disposed in the arc chamber 200 on the second end of the arc chamber 200 opposite the cathode 210. The repeller 220 may be in communication with repeller power supply 225. As the name suggests, the repeller 220 serves to repel the electrons emitted from the cathode 210 back toward the center of the arc chamber 200. For example, the repeller 220 may be biased at a negative voltage relative to the arc chamber 200 to repel the electrons. For example, the repeller power supply 225 may have an output in the range of 0 to −150V, although other voltages may be used. In certain embodiments, the repeller 220 is biased at between 0 and −150V relative to the arc chamber 200. In other embodiments, the repeller 220 may be grounded or floated.

In operation, a gas is supplied to the arc chamber 200. The thermionic electrons emitted from the cathode 210 cause the gas to form a plasma 250. Ions from this plasma 250 are then extracted through an extraction aperture 310 in the extraction plate. The ions are then manipulated to form an ion beam that is directed toward the workpiece.

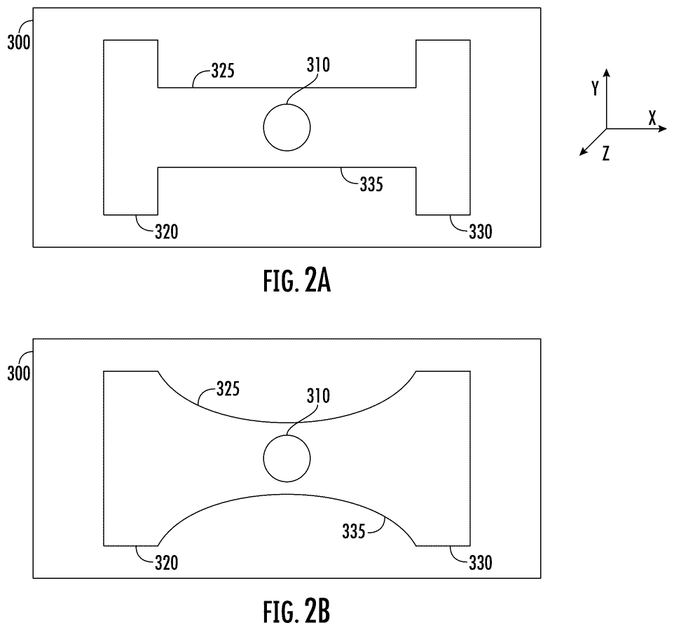

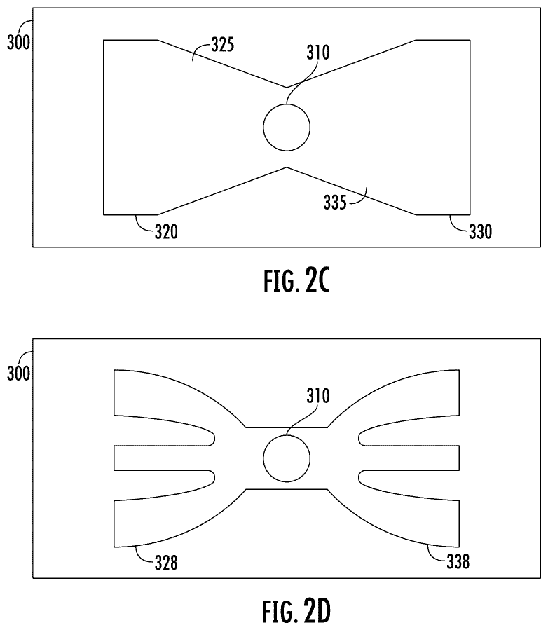

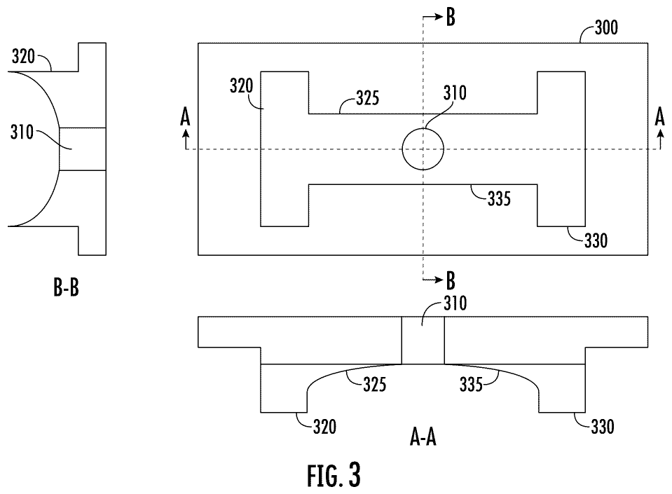

FIGS. 2A-2D show various embodiments of an extraction plate 300 that may be used in the ion source 290 of FIG. 1. The extraction plate 300 may be constructed of an electrically conductive material, such as tungsten, and may be in electrical communication with the rest of the arc chamber 200. In each embodiment, the direction from the first end to the second end is referred to as the width or X direction. The thickness of the extraction plate 300 is in the Z direction and may be between 0.02 and 0.2 inches, although other thicknesses are also possible. The direction that is orthogonal to both the X and Z directions is referred to as the height or Y direction and is the direction from one sidewall to the opposite sidewall. In each embodiment, the extraction plate 300 comprises an extraction aperture 310 through which ions pass. The extraction aperture 310 may be circular, or may be another shape. The extraction plate 300 is typically in physical contact with the sidewalls and ends of the arc chamber 200. When circular, the extraction aperture 310 may be disposed in the center of the extraction plate 300 in both the width and height directions.

In certain configurations, it may be beneficial for the region around the extraction aperture 310 to remain at an elevated temperature. Throughout this disclosure, the phrase “region around the extraction aperture” refers to a ring around the extraction aperture 310 that is at least ¼ inches larger in diameter than the extraction aperture 310. It is understood that the term “ring” refers to the area around the perimeter of the extraction aperture 310, even if the extraction aperture 310 is not round. For example, deposition along the extraction aperture 310 may be minimized by changing the temperature of the region around the extraction aperture 310. In certain embodiments, it may be beneficial to maintain the temperature of the region around the extraction aperture 310 at a very elevated temperature. In each of the embodiments described below, the thicker portions may be integral to the rest of the extraction plate 300. Thus, the thicker portions may be made from the same material as the rest of the extraction plate 300.

The cathode 210 and the repeller 220 are among the hottest components within the ion source 290. Thus, it may be beneficial to conduct the heat associated with these components toward the extraction aperture 310.

The embodiments in FIG. 2A-2D all include a first thicker portion, referred to as the cathode heat capture region 320, located above the front surface of the cathode 210. The phrase “located above” refers to the alignment of the cathode heat capture region 320 with respect to the front surface of the cathode 210 in the height and width directions. This first thicker portion is intended to capture heat emitted from the cathode 210. In some embodiments, the cathode heat capture region 320 is directly above the front surface of the cathode 210. In other embodiments, in may be offset from the front surface of the cathode 210 in the width direction. In some embodiments, the cathode heat capture region 320 may be at least half as large as the front surface of the cathode 210 in the width direction. In some embodiments, the cathode heat capture region 320 may be at most twice as large as the front surface of the cathode 210 in the width direction. Further, in some embodiments, the cathode heat capture region 320 may be at least half as large as the front surface of the cathode 210 in the height direction. In some embodiments, the cathode heat capture region 320 may be at most twice as large as the front surface of the cathode 210 in the height direction. A second thicker portion, known as the cathode heat conduction region 325, extends in the width direction from the cathode heat capture region 320 to the extraction aperture 310 and conducts heat from the cathode heat capture region 320 to the region around the extraction aperture 310. These embodiments may also include a third thicker portion, disposed above the repeller 220, referred to as the repeller heat capture region 330. As described above, the phrase “located above” refers to the alignment of the repeller heat capture region 330 with respect to the repeller 220 in the height and width directions. This third thicker portion is intended to capture heat emitted from the repeller 220. In some embodiments, the repeller heat capture region 330 is directly above the repeller 220. In other embodiments, in may be offset from the repeller 220. The dimensions of the repeller heat capture region 330 relative to the repeller 220 may be similar to that described for the cathode heat capture region 320 relative to the cathode 210. A fourth thicker portion, known as the repeller heat conduction region 335, extends in the width direction from the repeller heat capture region 330 to the extraction aperture 310 and conducts heat from the repeller heat capture region 330 to the region around the extraction aperture 310. In all of the embodiments described herein, the thicker portions extend further into the interior of the arc chamber 200 in the thickness direction than the rest of the extraction plate 300.

In FIG. 2A, the cathode heat capture region 320 is a rectangular prism and the cathode heat conduction region 325 is also formed as a rectangular prism. The cathode heat conduction region 325 may have the same thickness as the cathode heat capture region 320 or may be thinner. Additionally, the cathode heat conduction region 325 may have the same height as the cathode heat capture region 320 or may be much smaller in the height direction. In some embodiments, the ratio of the height of the cathode heat capture region 320 to the height of the cathode heat conduction region 325 may be 2:1 or greater. In some embodiments, the height of the cathode heat conduction region 325 is at least as large as the height of the extraction aperture 310. Similarly, the repeller heat capture region 330 is a rectangular prism and the repeller heat conduction region 335 is also formed as a rectangular prism. The repeller heat conduction region 335 may have the same thickness as the repeller heat capture region 330 or may be thinner. Additionally, the repeller heat conduction region 335 may have the same height as the repeller heat capture region 330 or may be much smaller in the height direction. In some embodiments, the ratio of the height of the repeller heat capture region 330 to the height of the repeller heat conduction region 335 may be 2:1 or greater. In some embodiments, the height of the repeller heat conduction region 335 is at least as large as the height of the extraction aperture 310. Further, in some embodiments, the shape and size of the cathode heat capture region 320 and the repeller heat capture region 330 may be identical. Similarly, in some embodiments, the shape and size of the cathode heat conduction region 325 and the repeller heat conduction region 335 may be identical. This allows the extraction plate 300 to be installed without a fixed orientation. In other embodiments, the cathode heat capture region 320 may be larger in the width and/or height direction than the repeller heat capture region 330.

FIG. 2B shows a second embodiment. In this embodiment, the cathode heat capture region 320 and the repeller heat capture region 330 are as described with respect to FIG. 2A. However, rather than being rectangular prisms, the cathode heat conduction region 325 and the repeller heat conduction region 335 are curved in the height direction such that the heat conduction regions are the same height as the cathode heat capture region 320 and the repeller heat capture region 330 at their distal ends and much smaller at their proximal ends, near the extraction aperture 310. In some embodiments, the ratio of the height of the heat conduction regions at their distal end to the height of the heat conduction regions at their proximal end may be 2:1 or greater.

FIG. 2C shows a third embodiment. In this embodiment, the cathode heat capture region 320 and the repeller heat capture region 330 are as described with respect to FIG. 2A. However, rather than being rectangular prisms, the cathode heat conduction region 325 and the repeller heat conduction regions 335 are linearly sloped in the height direction such that the heat conduction regions are the same height as the cathode heat capture region 320 and the repeller heat capture region 330 at their distal ends and much smaller at their proximal ends, near the extraction aperture 310. In some embodiments, the ratio of the height of the heat conduction regions at their distal end to the height of the heat conduction regions at their proximal end may be 2:1 or greater.

In summary, FIGS. 2A-2C all show the cathode heat capture region 320 and the repeller heat capture region 330 as being rectangular prisms. In each embodiment, the distal ends of the heat conduction regions connect the cathode heat capture region 320 and repeller heat capture region 330, while the proximal ends of the heat conduction regions terminate at the extraction aperture 310. In many embodiments, the proximal ends of the two heat conduction regions are much smaller in the height direction than the cathode heat capture region 320 and repeller heat capture region 330. Further, the proximal ends of the two heat conduction regions contact each other at the extraction aperture 310.

Note that while FIGS. 2A-2C show three different shapes for the heat conduction regions, the disclosure is not limited to these shapes. The heat conduction regions may be any suitable shape that includes a distal end that connects to the cathode heat capture region 320 and the repeller heat capture region 330 and a proximal end that is much smaller in the height direction near the extraction aperture 310. As an example, while FIG. 2B shows the heat conduction regions as being concave curves, convex curves may also be used.

In some embodiments, the cathode heat capture region 320 and the repeller heat capture region 330 are not rectangular prisms. They may be oval, elliptical or another shape.

For example, as shown in FIG. 2D, the cathode heat capture region 320 and the cathode heat conduction region 325 may be formed as a plurality of cathode conduction fingers 328. These cathode conduction fingers 328 may merge together at or before the extraction aperture 310. These cathode conduction fingers 328 focus the heat generated by the cathode 210 toward the extraction aperture 310, thus focusing heat at this region. Similarly, the repeller heat capture region 330 and the repeller heat conduction region 335 may be formed as a plurality of repeller conduction fingers 338. These repeller conduction fingers 338 may merge together at or before the extraction aperture 310 so as to focus the heat toward the extraction aperture 310.

FIG. 3 shows another example of an extraction plate 300 that may be used with the ion source of FIG. 1 in which the cathode heat capture region 320 and the repeller heat capture region 330 are not rectangular prisms. The bottom view of the extraction plate 300 looks similar to that of FIG. 2A, however, the thickness of the various regions is different in this embodiment. For example, in certain embodiments, to extract as much heat as possible from the cathode 210 and the repeller 220, the cathode heat capture region 320 and the repeller heat capture region 330 may be formed to have a shape in the thickness direction that corresponds to the shape of the cathode 210 and repeller 220, respectively. In this figure, the cathode heat capture region 320 and the repeller heat capture region 330 are formed as inverted semicircles, having a radius that is slightly larger than the radius of the cathode 210 and repeller 220, respectively. For example, the radius of the cathode heat capture region 320 may be at least 0.02 inches greater than that of the cathode 210. Further, the cathode heat conduction region 325 may also taper from a larger thickness at the distal end to a smaller thickness at the proximal end. For example, the ratio of the thickness of the cathode heat conduction region at the distal end to the thickness at the proximal end may be 2:1 or greater in some embodiments. In other embodiments, the cathode heat conduction region 325 may be as described in any of the embodiments above.

Note that the concept of a conformal cathode heat capture region 320 may also be applied to the repeller heat capture region 330.

Further, the concept of conformal heat capture regions may also be applied to the embodiments shown in FIGS. 2B-2C. In these embodiments, the side view of the cathode heat capture region 320 and repeller heat capture region 330 may be similar to that shown in the B-B view of FIG. 3. The side view of the cathode heat conduction region 325 and the repeller heat conduction region 335 may be similar to that shown in the A-A view of FIG. 3.

In certain embodiments, the cathode heat capture region 320 and the repeller heat capture region 330 are configured such that neither contacts the first end, the second end or the side walls 201. In some embodiments, the distance between the cathode heat capture region 320 and the first end is between 0.030 and 0.050 inches. This may create a preferential path for the heat from the cathode 210 and the repeller 220 to travel to the area near the extraction aperture 310.

Note that in some embodiments, the ion source 290 may not include a repeller 220. In these embodiments, the repeller heat capture region 330 and the repeller heat conduction region 335 may be omitted.

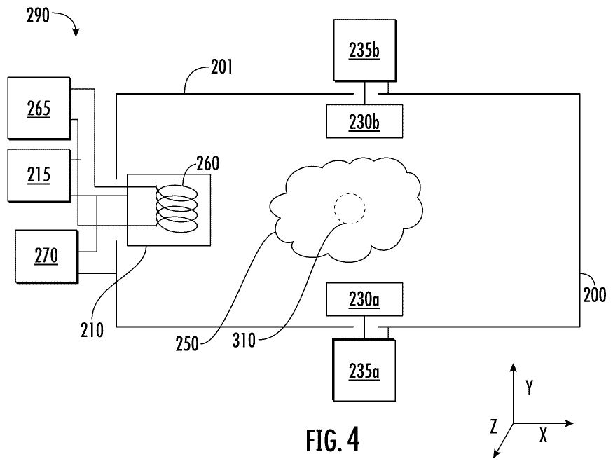

FIG. 4 shows a second embodiment of an ion source 290. Many of the components in this ion source are the same as those described with respect to FIG. 1 and will not be described again. However, in this embodiment, there is no repeller in the arc chamber 200. Rather, one or two side electrodes 230a, 230b, which are disposed along the side walls 201 of the arc chamber 200, may be employed. In some embodiments, each side electrode 230a, 230b is in communication with a respective electrode power supply 235a, 235b. In other embodiments, one of the side electrodes may be grounded or electrically floating, and one of the electrode power supplies may be eliminated. In the embodiment shown in FIG. 4, the cathode 210 and the side electrodes 230a, 230b generate much of the heat in the ion source 290.

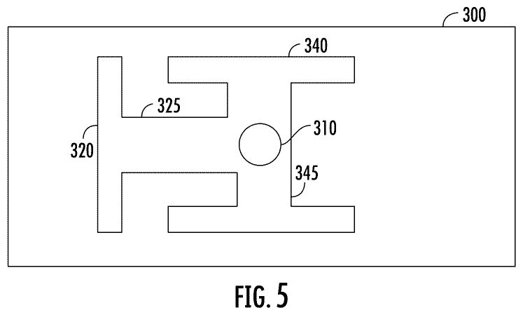

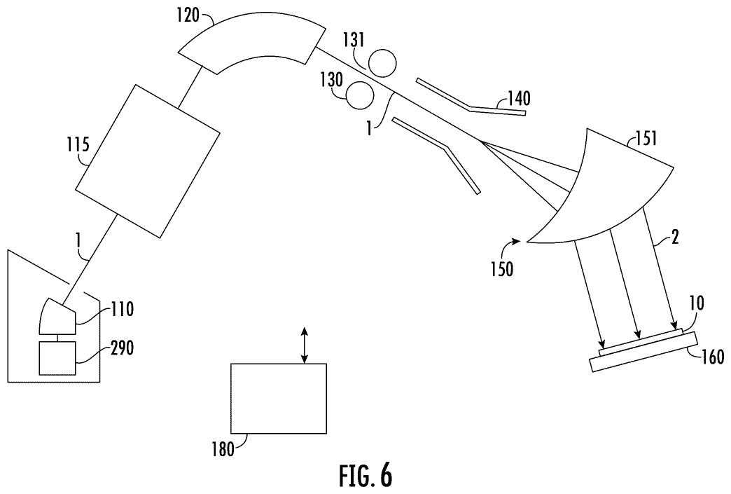

Therefore, in this embodiment, as shown in FIG. 5, the extraction plate 300 is formed to have a cathode heat capture region 320 and a cathode heat conduction region 325, as was described above. The cathode heat capture region 320 and the cathode heat conduction region 325 represent the first and second thicker portions, respectively. Additionally, one or two third thicker portions, referred to as the electrode heat capture regions 340 are located above the side electrodes 230a, 230b. Further, one or two fourth thicker portions, referred to as the electrode heat conduction regions 345 extend in the height direction and are disposed between the corresponding electrode heat capture regions 340 and the extraction aperture 310. While FIG. 5 shows the cathode heat conduction region 325 and the electrode heat conduction regions 345 as rectangular prisms, it is understood that these regions may be any suitable shape, such as those shown in FIGS. 2B-2D. Note that the dimensions of the electrode heat conduction region 345 relative to the electrode heat capture region 340 may be the same as was described above with respect to the cathode heat conduction region 325 and the cathode heat capture region 320. Further, the cathode heat capture region 320 and the electrode heat capture regions 340 may be conformally shaped, as described with respect to FIG. 3, such that a constant distance exists between the side electrodes 230a, 230b and the respective electrode heat capture regions 340.

Note that in some embodiments, the ion source 290 may include a cathode 210, a repeller 220 and one or more side electrodes 230a, 230b. In this embodiment, the extraction plate 300 may include a cathode heat capture region 320, a cathode heat conduction region 325, a repeller heat capture region 330, a repeller heat conduction region 335, one or more electrode heat capture regions 340 and one or more corresponding electrode heat conduction regions 345.

FIG. 6 shows a beam line ion implantation system. Disposed outside and proximate the extraction aperture of the ion source 290 are extraction optics 110. In certain embodiments, the extraction optics 110 comprise one or more electrodes. Each electrode may be a single electrically conductive component with an aperture disposed therein. Alternatively, each electrode may be comprised of two electrically conductive components that are spaced apart so as to create the aperture between the two components. The electrodes may be a metal, such as tungsten, molybdenum or titanium. One or more of the electrodes may be electrically connected to ground. In certain embodiments, one or more of the electrodes may be biased using an electrode power supply. The electrode power supply may be used to bias one or more of the electrodes relative to the ion source so as to attract ions through the extraction aperture. The extraction aperture and the aperture in the extraction optics are aligned such that the ions 1 pass through both apertures.

Located downstream from the extraction optics 110 are one or more beam line components. The beam line components guide the ions from the ion source toward the workpiece. In some embodiments, a mass analyzer 120 is located downstream from the extraction optics 110. An acceleration/deceleration column 115 may be positioned between the extraction optics 110 and mass analyzer 120. The mass analyzer 120 uses magnetic fields to guide the path of the extracted ions 1. The magnetic fields affect the flight path of ions according to their mass and charge. A mass resolving device 130 that has a resolving aperture 131 is disposed at the output, or distal end, of the mass analyzer 120. By proper selection of the magnetic fields, only those ions 1 that have a selected mass and charge will be directed through the resolving aperture 131. Other ions will strike the mass resolving device 130 or a wall of the mass analyzer 120 and will not travel any further in the system. The ions that pass through the mass resolving device 130 may form a spot beam.

The spot beam may then enter a scanner 140 which is disposed downstream from the mass resolving device 130. The scanner 140 causes the spot beam to be fanned out into a plurality of divergent beamlets. The scanner 140 may be electrostatic or magnetic. The scanner 140 may comprise spaced-apart scan plates connected to a scan generator. The scan generator applies a scan voltage waveform, such as a sawtooth waveform, for scanning the ion beam in accordance with the electric field between the scan plates. Angle corrector 150 is designed to deflect ions in the scanned ion beam to produce scanned ion beam 2 having parallel ion trajectories, thus focusing the scanned ion beam. Specifically, the angle corrector 150 is used to alter the diverging ion trajectory paths into substantially parallel paths of a scanned ion beam 2. In particular, angle corrector 150 may comprise magnetic pole pieces 151 which are spaced apart to define a gap and a magnet coil (not shown) which is coupled to a power supply. The scanned ion beam 2 passes through the gap between the magnetic pole pieces 151 and is deflected in accordance with the magnetic field in the gap. The magnetic field may be adjusted by varying the current through the magnet coil. Beam scanning and beam focusing are performed in a selected plane, such as a horizontal plane.

The workpiece 10 is disposed on a movable workpiece holder 160. In certain embodiments, the forward direction of the scanned ion beam 2 is referred to as the Z-direction, the direction perpendicular to this direction and horizontal may be the X-direction, referred to as while the direction perpendicular to the Z-direction and vertical may be referred to as the Y-direction. In this example, it is assumed that the scanner 140 scans the spot beam in the X-direction while the movable workpiece holder 160 is translated in the Y-direction.

The rate at which the scanner 140 scans the spot beam in the X-direction may be referred to as beam scan speed or simply scan speed.

Thus, in operation, the movable workpiece holder 160 moves in the Y direction from a first position, which may be above the scanned ion beam 2 to a second position, which may be below the scanned ion beam 2. The movable workpiece holder 160 then moves from the second position back to the first position. During this time, the spot beam is being scanned in the X direction, ensuring that the entirety of the workpiece 10 is exposed to the spot beam.

A controller 180 is also used to control the system. The controller 180 has a processing unit and an associated memory device. This memory device contains the instructions, which, when executed by the processing unit, enable the system to perform the functions described herein. This memory device may be any non-transitory storage medium, including a non-volatile memory, such as a FLASH ROM, an electrically erasable ROM or other suitable devices. In other embodiments, the memory device may be a volatile memory, such as a RAM or DRAM. In certain embodiments, the controller 180 may be a general purpose computer, an embedded processor, or a specially designed microcontroller. The actual implementation of the controller 180 is not limited by this disclosure.

The system described herein have many advantages. As described above, certain species may tend to condense and form depositions on the surfaces of the ion source. By creating an extraction plate with raised interior features, preferential heat transfer pathways are created. These heat transfer pathways conduct heat from the hottest components within the arc chamber, including the cathode, the repeller (if present), and the side electrodes (if present) to the area surrounding the extraction aperture. This maintains the region around the extraction aperture at an elevated temperature, which serves to discourage the formation of deposits near the extraction aperture. Further, the concepts are applicable for ion sources with repellers, as well as ion sources that include side electrodes.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. An ion source, comprising:
an arc chamber having a first end, a second end and side walls connecting the first end and the second end, wherein a direction from the first end to the second end is defined as a width direction and a direction from a first sidewall to an opposite sidewall is defined as a height direction;
a cathode disposed within the arc chamber at the first end; and
an extraction plate disposed on the arc chamber, the extraction plate comprising:
an extraction aperture;
a first thicker portion disposed above the cathode, referred to as a cathode heat capture region; and
a second thicker portion, referred to as a cathode heat conduction region, disposed in the width direction between the cathode heat capture region and the extraction aperture, wherein heat from the cathode travels through the cathode heat capture region and the cathode heat conduction region to an area around the extraction aperture to increase a temperature of the area.

2. The ion source of claim 1, wherein the arc chamber comprises a repeller disposed at the second end; and
wherein the extraction plate comprises:
a third thicker portion disposed above the repeller, referred to as a repeller heat capture region; and
a fourth thicker portion, referred to as a repeller heat conduction region, disposed in the width direction between the repeller heat capture region and the extraction aperture, wherein heat from the repeller travels through the repeller heat capture region and the repeller heat conduction region to the area around the extraction aperture to increase the temperature of the area.

3. The ion source of claim 2, wherein the cathode heat capture region and the repeller heat capture region are a same shape and size, and wherein the cathode heat conduction region and the repeller heat conduction region are a same shape and size.

4. The ion source of claim 1, wherein the cathode heat conduction region is narrower in the height direction than the cathode heat capture region.

5. The ion source of claim 1, wherein the cathode heat capture region comprises a rectangular prism.

6. The ion source of claim 1, wherein the cathode heat capture region has a thickness that corresponds to a shape of the cathode.

7. The ion source of claim 1, wherein the cathode heat conduction region comprises a rectangular prism having a height less than a height of the cathode heat capture region.

8. The ion source of claim 1, wherein the cathode heat conduction region comprises a curved shape having a distal end in contact with the cathode heat capture region and a proximal end near the extraction aperture, smaller in the height direction than the distal end.

9. The ion source of claim 1, wherein the cathode heat conduction region comprises a linearly sloped shape having a distal end in contact with the cathode heat capture region and a proximal end near the extraction aperture, smaller in the height direction than the distal end.

10. The ion source of claim 1, wherein the cathode heat capture region and the cathode heat conduction region comprise a plurality of cathode conduction fingers that merge at or before the extraction aperture.

11. The ion source of claim 1, wherein the cathode heat capture region does not contact the first end or the side walls.

12. The ion source of claim 1, wherein the arc chamber comprises a side electrode disposed at one of the side walls; and
wherein the extraction plate comprises:
a third thicker portion disposed above the side electrode, referred to as an electrode heat capture region; and
a fourth thicker portion, referred to as an electrode heat conduction region, disposed in the height direction between the electrode heat capture region and the extraction aperture, wherein heat from the side electrode travels through the electrode heat capture region and the electrode heat conduction region to the area around the extraction aperture to increase the temperature of the area.

13. An ion implantation system, comprising:
the ion source of claim 1 to generate an ion beam;
a workpiece holder to hold a workpiece; and
one or more beamline components disposed between the ion source and the workpiece holder to guide the ion beam toward the workpiece.

14. An extraction plate for use with an indirectly heated cathode ion source and adapted to be disposed on an arc chamber containing a cathode at a first end and a repeller at a second end, the extraction plate comprising:
an extraction aperture;
a first thicker portion disposed above the cathode, referred to as a cathode heat capture region;
a second thicker portion, referred to as a cathode heat conduction region, disposed in a width direction between the cathode heat capture region and the extraction aperture, wherein heat from the cathode travels through the cathode heat capture region and the cathode heat conduction region to an area around the extraction aperture to increase a temperature of the area;
a third thicker portion disposed above the repeller, referred to as a repeller heat capture region; and
a fourth thicker portion, referred to as a repeller heat conduction region, disposed in the width direction between the repeller heat capture region and the extraction aperture, wherein heat from the repeller travels through the repeller heat capture region and the repeller heat conduction region to the area around the extraction aperture to increase the temperature of the area.

15. The extraction plate of claim 14, wherein the cathode heat capture region and the repeller heat capture region are a same shape and size, and wherein the cathode heat conduction region and the repeller heat conduction region are a same shape and size.

16. The extraction plate of claim 14, wherein the cathode heat capture region and the repeller heat capture region each comprises a rectangular prism.

17. The extraction plate of claim 14, wherein the cathode heat capture region has a thickness that corresponds to a shape of the cathode and the repeller heat capture region has a thickness that corresponds to a shape of the repeller.

18. The extraction plate of claim 14, wherein the cathode heat conduction region and the repeller heat conduction region are each larger than the extraction aperture in a height direction.

19. The extraction plate of claim 14, wherein the cathode heat conduction region and the repeller heat conduction region each comprises a rectangular prism having a height less than a height of the cathode heat capture region and the repeller heat capture region, respectively.

20. The extraction plate of claim 14, wherein the cathode heat conduction region and the repeller heat conduction region each comprises a curved shape or a linearly sloped shape having a distal end in contact with the cathode heat capture region and the repeller heat capture region, respectively and a proximal end near the extraction aperture, smaller in a height direction than the distal end.
